(19) United States
(12) Patent Application Publication
(10) Pub. No.: US 2015/0083191 A1
(43) Pub. Date: Mar. 26, 2015

(54) PHOTOVOLTAIC MODULE AND USE THEREOF

(71) Applicant: Gernot Gmundner, Kraubath (AT)

(72) Inventor: Gernot Gmundner, Kraubath (AT)

(73) Assignee: AT & S Austria Technologie & Systemtechnik Aktiengesellschaft, Leoben-Hinterberg (AT)

(21) Appl. No.: 14/356,802

(22) PCT Filed: Jun. 5, 2012
(86) PCT No.: PCT/AT2012/000154

§ 371 Date: May 7, 2014

(30) Foreign Application Priority Data
Jun. 7, 2011 (AT) GM 327/2011

(51) Int. Cl. H02S 30/20; H01L 31/02

(52) U.S. Cl. CPC H02S 30/20; H01L 31/0201
USPC 136/245

(57) ABSTRACT

In the case of a photovoltaic module which comprises a plurality of solar cells which are each coupled to an electrically conductive, structured layer for discharging the electrical energy generated in the solar cells, wherein at least two subregions of the photovoltaic module are coupled to one another via a flexible connecting region, provision is made for the solar cells to be coupled on the rear side of said solar cells to the electrically conductive, structured layer, and for the electrically conductive, structured layer to be integrated in a multilayered film arranged on the rear side of the solar cells, wherein the multilayered film forms the flexible connecting region between the at least two subregions of the photovoltaic module, as a result of which a photovoltaic module which can be tilted or folded can be made available.

This is a national stage of PCT/AT2012/000154 filed Jun. 5, 2012 and published in German, which has a priority of Austria no. GM 327/2011 filed Jun. 7, 2011, hereby incorporated by reference.

### FIELD OF THE INVENTION

The present invention relates to a photovoltaic module which comprises a plurality of solar cells that are each coupled to an electrically conducting or conductive and structured layer or structure for discharging the electrical energy generated in the solar cells, wherein at least one transparent carrier layer is provided on the surface of the solar ceils facing away from the electrically conducting layer or structure, wherein the electrically conducting and structured layer or structure can be contacted with connections of a connection housing, wherein at least two subregions of the photovoltaic module which each have at least one solar cell are coupled to one another via a flexible connecting region and can be folded or tilted along the flexible connecting region into a position in which they are angled, relative to one another and/or at least partially overlap one another. The present invention, moreover, relates to the use of such a photovoltaic module.

### PRIOR ART

A photovoltaic module usually comprises a plurality of solar cells in a substantially planar or plane arrangement, wherein discharging of the electrical energy generated, in the solar cells is effected via an electrically conducting or conductive and structured layer or structure. To protect the solar cells, a transparent carrier layer made, for instance, of glass is provided, and on the side of the photovoltaic module facing away from the carrier layer a cover layer is usually provided, which, for instance, covers the electrically conducting and structured layer or structure, said conducting layer or structure being contactable with connections of a connection housing.

In order to achieve an appropriately high energy output, photovoltaic modules having comparatively large dimensions have been provided or made available to an increasing extent, wherein such photovoltaic modules having large dimensions will not only become difficult to handle, but increasingly also have comparatively high weights, since correspondingly thick materials will, for instance, have to be provided for the transparent carrier layer in order to provide sufficient mechanical strength. While, when mounting such photovoltaic modules, for instance, on building parts, in particular roof surfaces, an appropriately safe and reliable anchorage and retention or support of such large-area photovoltaic modules are possible, it is immediately apparent that large-area photovoltaic modules providing a correspondingly high energy output will no longer be reasonably available in a transportable form and/or readily usable and, optionally, simply mountable or dismountable form, bearing in mind, in particular, their large and unwieldy dimensions as well as their possibly high weights.

To at least partially solve the problem of transport, partially foldable configurations are proposed in US 2008/0314434 or WO 2006/098974, which, however, require the complex wiring of individual solar cells.

### SUMMARY OF THE INVENTION

The present invention, therefore, aims to provide a photovoltaic module of the initially defined kind, by which the problems of the above-cited prior art can be avoided, or at least reduced, and, in particular, aims to provide a photovoltaic module which, in a transport position, is formed with reduced dimensions relative to a position of use, and/or with configurations deviating from a large-area, plane structure, while simultaneously enabling simple wiring between the solar cells or subregions of the module.

To solve these objects, a photovoltaic module of the initially defined kind is essentially characterized in that the solar cells on their rear side are coupled to the electrically conducting or conductive and structured layer, which is covered by a cover layer, and that the electrically conducting or conductive and structured layer is integrated in a multilayered film arranged on the rear side of the solar cells, wherein the multilayered film forms the flexible connecting region between the at least two subregions of the photovoltaic module and/or a component thereof. Since at least two subregions of the photovoltaic module are coupled to one another via a flexible connecting region, such a photovoltaic module can be arranged or positioned in a position deviating from a substantially plane, large-area configuration. In order to facilitate the electric coupling between the individual subregions or solar ceils of the module, it is proposed according to the invention that the solar cells on their rear side are coupled to the electrically conducting or conductive and structured layer, which is covered by a cover layer. In this respect, it is proposed, in order to further simplify the construction of the photovoltaic module according to the invention, that the electrically conducting or conductive and structured layer is integrated in a multilayered film arranged on the rear side of the solar cells, wherein the multilayered film forms the flexible connecting region between the at least two subregions of the photovoltaic module and/or a component thereof. In this manner, a photovoltaic module according to the invention comprising subregions that are connected to one another via at least one flexible connecting region and each include at least one solar cell can also be folded or tilted into a position of the subregions at least partially overlapping one another, for instance for transport purposes, in order to enable the transport of such a photovoltaic module at reduced external dimensions with a simple and reliable wiring or electric coupling of the solar cells and/or subregions. A portable and easily transportable photovoltaic module can thus be provided, which, for use in a simple and reliable manner, can be brought into a position or state in which the subregions respectively connected to one another via flexible connecting regions can be brought into a position optimized for the generation of energy, with the electric coupling integrated in the flexible subregions. The flexible connecting regions between the individual subregions will also enable the individual subregions to assume relatively angled positions in order to each enable the optimized generation of energy as a function of the respectively required demands.

In order to achieve an appropriately small overall size in a transport position and, optionally, also facilitate the control of the solar cells provided in the individual subregions, it is proposed according to a preferred embodiment that the at least two subregions each have substantially identical dimensions and/or an identical number of solar cells.

For the simple adaptation to possibly different purposes of use and, in particular, also in order to optimize the surfaces of the subregions of the module for the arrangement of the solar cells, whose number will, in particular, essentially determine or influence the overall performance of the photovoltaic module, it is proposed according to a further preferred embodiment that the subregions of the photovoltaic module have a regular geometric configuration such as a rectangular, in particular square, triangular, hexagonal configuration.

For the simple and reliable electric coupling of the conducting layers or structures received in the individual subregions and coupled to the solar cells, it is proposed that the conducting or conductive and structured layer or structure is embedded in the flexible connecting region, as in correspondence with a further preferred embodiment of the photovoltaic module according to the invention.

In order to simplify the constructional setup of the photovoltaic module and to achieve an appropriate stability and mechanical resistance of the individual subregions of the photovoltaic module, it is, moreover, preferably proposed that the subregions respectively connected to one another via a flexible connecting region each comprise a plurality of solar cells and are formed with a transparent carrier layer collectively covering all of the solar cells of said subregion. In particular, when considering the fact that the individual subregions have reduced dimensions as compared to a rigid photovoltaic module having large dimensions, carrier layers having correspondingly reduced thicknesses or strengths will do with the required mechanical stability being nevertheless ensured.

For the reliable control of the solar cells received in the individual subregions, it is, moreover, proposed that a control device is associated to at least each of the subregions of the photovoltaic module, as in correspondence with a further preferred embodiment of the photovoltaic module according to the invention. By providing for, or associating to, each of the subregions a control device, it will, in particular, be ensured that in the event of a possible different irradiation of the individual subregions, which might otherwise lead to overheating of individual solar cells or subregions, such different environmental parameters can be taken into account in a simple and reliable manner. By providing suitable control devices, it will be possible to optimize the overall performance of the photovoltaic module while avoiding damage to individual solar cells or subregions, even at a possibly occurring partial shadowing of individual solar ceils or subregions, and hence different outputs of different subregions.

In order to allow for the simple arrangement or folding of a possibly present plurality of subregions of the photovoltaic module, which are each connected to one another via flexible subregions, it is proposed according to a further preferred embodiment that the dimensions of flexible connecting regions between individual, mutually overlapping subregions of the photovoltaic module are each a multiple of, in particular at least twice, the thickness of a subregion of the photovoltaic module.

In order to take into account possibly different relative distances between individual subregions that are foldable on top of one another, it is, moreover, proposed that the dimensions of the flexible connecting regions between subregions of the photovoltaic module are selected to differ from one another, as in correspondence with a further preferred embodiment of the photovoltaic module according to the invention.

As already mentioned above several times, it is possible to facilitate the transport of a photovoltaic module according to the invention by the subregions being able to be angled relatively to one another or brought into an overlapping position such that it is proposed according to the invention to use the photovoltaic module according to the invention, or a preferred embodiment thereof, as a transportable photovoltaic module to be used in a folded or tilted transport condition.

In addition, it is proposed to use the photovoltaic module according to the invention, or a preferred embodiment thereof, as a photovoltaic module to be used with relatively angled subregions.

### SHORT DESCRIPTION OF THE DRAWINGS

In the following, the invention will be explained in more detail by way of exemplary embodiments of photovoltaic modules, which are schematically illustrated in the accompanying drawing. Therein:

FIG. 1 is a schematic section through a subregion of a photovoltaic module according to the invention;

FIG. 2 is a top view of an embodiment of a photovoltaic module according to the invention, wherein a plurality of substantially square subregions are each mutually connected via flexible connecting regions, FIG. 1 depicting, for instance, a section along line I-I of FIG. 2 on an enlarged scale;

FIG. 3 illustrates a further modified embodiment of a photovoltaic module according to the invention, FIG. 3a showing the photovoltaic module in a folded transport position and FIG. 3b showing the photovoltaic module in a partially unfolded position or position of use;

FIG. 4 is a schematic top view of a further modified embodiment of a photovoltaic module according to the invention, wherein substantially triangular subregions are provided; and

FIG. 5, in an illustration similar to those of FIGS. 2 and 4, depicts a top view of a further modified embodiment, wherein a substantially central, hexagonal, middle subregion of the photovoltaic module can be connected or coupled to a corresponding number of substantially triangular subregions that can be tilted or folded into a position overlapping the central hexagonal subregion.

### DETAILED DESCRIPTION OF PREFERRED EMBODIMENTS

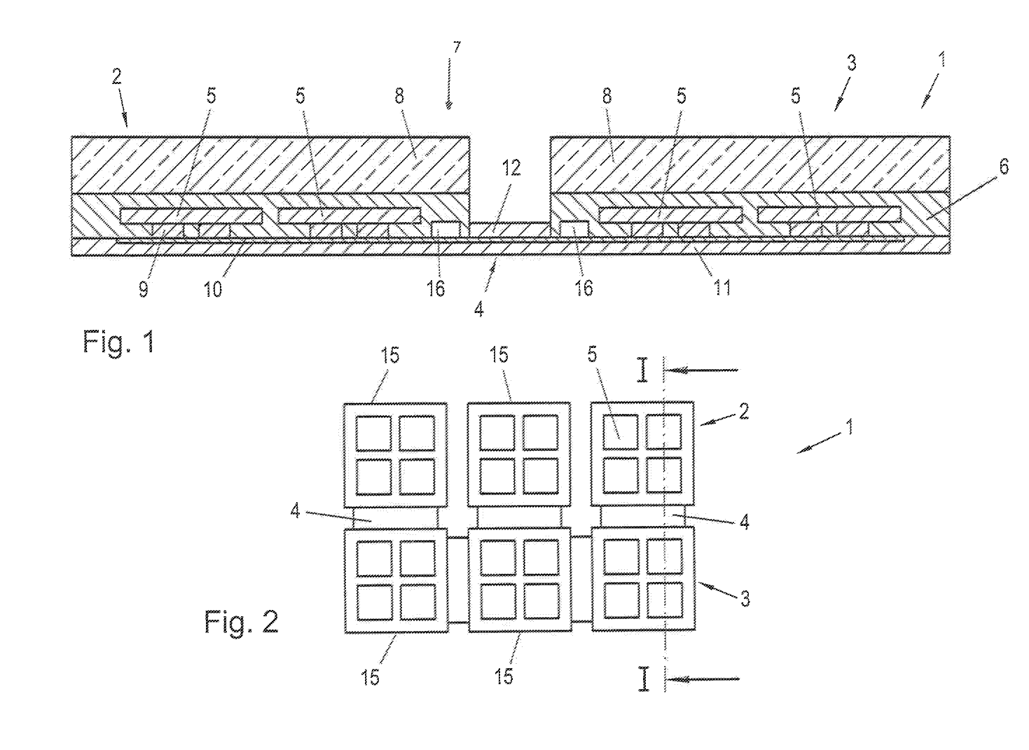

FIG. 1 depicts a section through a photovoltaic module 1, from which it is apparent that subregions 2 and 3 of the photovoltaic module are coupled or connected to each other via a flexible connecting region denoted by 4.

Each of the subregions 2 and 3 of the photovoltaic module 1 comprises a plurality of solar cells 5, which are embedded in a layer 6 of synthetic material consisting, for instance, of ethylene vinyl acetate. The solar cells 5 are, moreover, covered by a transparent cover layer 8 made, for instance, of glass in the direction towards an irradiation environment schematically indicated by 7.

For discharging the electrical energy generated in the solar cells 5, the latter are connected to an electrically conducting or conductive and structured layer or structure 10 via contacts schematically indicated by 9, said discharging of energy being effected via a connection housing (not illustrated) using the conducting layer or structure 10.

A cover film or layer 11 is, moreover, provided for the protection of the conducting layer or structure 10.

From FIG. 1, it is apparent that the connection or coupling between the subregions 2 and 3 of the photovoltaic module, which each comprise a plurality of solar cells 5, is realized via the cover film or layer 11 and the electrically conducting layer or structure 10, wherein an additional protective layer or cover layer 12 of the flexible connecting region 4 is, moreover, indicated. The coupling or wiring of individual solar cells 5 and of the subregions 2 and 3, respectively, is realized via a composite film in which is also integrated the electrically conducting layer or structure 10 besides the layers or plies for achieving the mechanical strength.

As will be discussed in detail below with reference to the subsequent Figures, it has thus become possible, by coupling or connecting the subregions 2 and 3 of the photovoltaic module 1, which each comprise a plurality of solar cells 5, to bring the individual subregions 2 and 3 in a relatively angled position or at least partially overlapping position so as to enable the adaptation to different requirements or configurations of use of the photovoltaic module 1, or the assumption of a transport position in which the photovoltaic module 1 has a correspondingly reduced size.

In FIG. 1, a control device is, moreover, schematically indicated by 16 in each of the subregions 2 and 3, which control device, in addition to optimizing the energy output to be provided by the photovoltaic module 1, also enables the protection and/or separate control of the individual subregions 2 and 3.

FIG. 2 schematically illustrates that the photovoltaic module 1, in addition to subregions 2 and 3 as illustrated in FIG. 1 on an enlarged scale, which are coupled or connected via the connecting region again denoted by 4, comprises further subregions generally denoted by 15 and again having substantially square dimensions. All of the subregions 2, 3 and 15 each comprise four solar cells 5 in the square array illustrated, the respective flexible connecting regions between individual adjacent subregions 2, 3 and 15 being generally denoted by 4.

According to demands, a desired number of subregions 2, 3 and 15 to be coupled or connected to one another can thus be provided for the photovoltaic module 1.

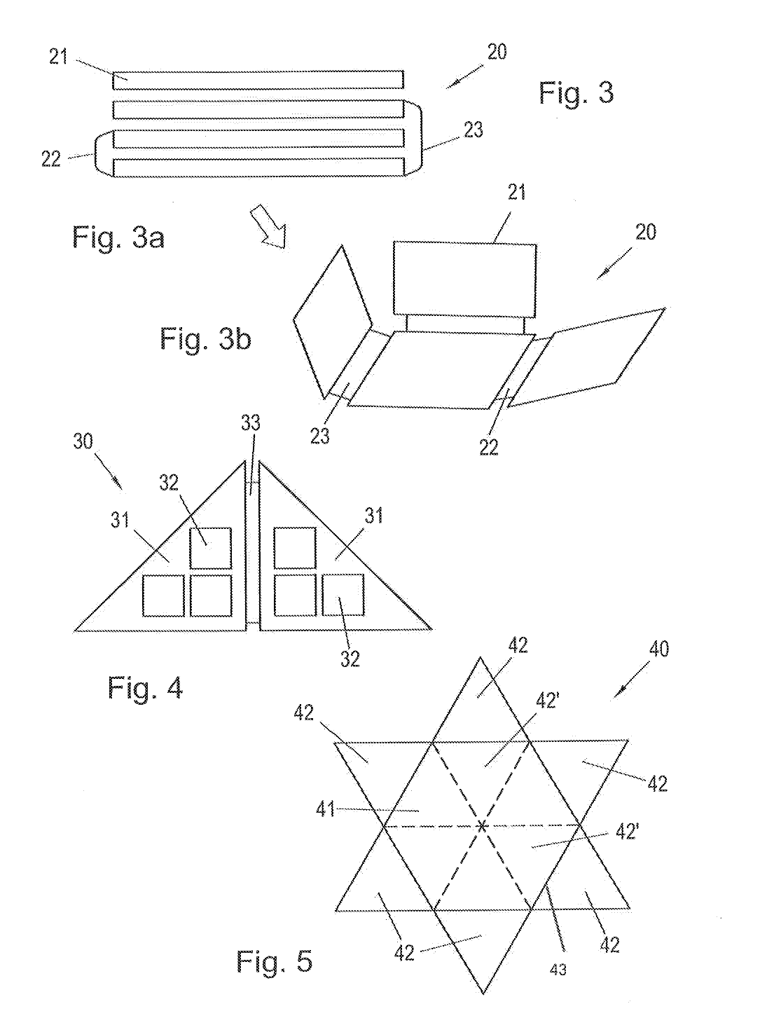

From the schematic illustration according to FIG. 3, it is apparent that a photovoltaic module 20 again consisting of a plurality of subregions generally denoted by 21 can be brought into a transport position illustrated in FIG. 3a, in which the individual subregions 21, which again comprise a plurality of solar cells, which are, however, not illustrated for the sake of simplicity, are brought into a mutually overlapping position. Individual connecting regions between adjacent or adjoining subregions 21 are denoted by 22 and 23 in FIG. 3a, From the schematic illustration of FIG. 3a, it can, moreover, be taken that the connecting regions 22 and 23 have different lengths as a function of the relative positioning of the subregions 21 in the transport position. These lengths, in particular, are each a multiple of the thickness of the individual subregions 21.

From the transport position depicted in FIG. 3a with correspondingly reduced overall dimensions, the photovoltaic module 20 can be unfolded or tilted out into the position indicated in FIG. 3b such that in a position of use a correspondingly large active surface of the photovoltaic module 20 can again be provided by the plurality of subregions again generally denoted by 21. In this case, the individual subregions 21 need not be brought into a substantially flat or plane position or arrangement, but may also have or assume a mutually angled position according to demands.

FIG. 4 depicts a further modified embodiment of a photovoltaic module 30, wherein subregions 31 each having a triangular configuration and comprising solar cells schematically indicated by 32 are connected or coupled to one another via a flexible connecting region 33. According to demands, the subregions 31 can also be brought into a relatively angled position or, in particular when providing substantially identical dimensions, into a completely superimposed, or overlapping position.

FIG. 5 depicts a further modified embodiment of a photovoltaic module 40, wherein a plurality of triangular subregions 42 are each coupled or connected to a central, hexagonal subregion 41 via schematic connecting regions 43. In FIG. 5, the triangular subregions 42 are indicated in their unfolded positions by full lines, while the transport position, which has a correspondingly smaller external dimension and in which the subregions 42, which can be pivoted or tilted about the connecting regions 43, substantially completely cover or overlap the central, middle subregion 41, is indicated by broken lines at 42′.

As in FIG. 3b, the individual solar cells received in subregions 41 and 42 are not illustrated in detail in FIG. 5 for simplification of the illustration.

The electric coupling of the individual solar cells and subregions in the configurations according to FIGS. 2 to 5 is realized via a conducting structure or layer 10, or a composite film, as in the embodiment depicted in FIG. 1.

By providing suitable subregions 2, 3, 15, 21, 31 as well as 41 and 42 having dimensions reduced relative to the overall dimensions of the photovoltaic module 1, 20, 30 and 40, respectively, small thicknesses will, for instance, do for the transparent carrier layer 8, since a sufficient mechanical resistance can be provided despite the small thicknesses of the subregions having correspondingly small dimensions.

The subregions 2, 3, 15, 21, 31, 41 and 42, which are each coupled to one another via flexible connecting regions 4, 22, 23, 33 and 43, respectively, allow for an increased flexibility of use of the photovoltaic module 1, 20, 30, 40 by enabling adaptation to different circumstances. The photovoltaic module can, moreover, be brought into a transport position having reduced external dimensions relative to those in the position of use while enabling a simple wiring or electric coupling of individual solar cells or subregions so as to provide a transportable photovoltaic module having comparatively small dimensions that are easy to handle.

Such a transportable photovoltaic module 1, 20, 30, 40 can, for instance, be used for energy supply independently of an, in particular, public power grid, or as an emergency energy supply unit. Similarly, such a transportable photovoltaic module 1, 20, 30, 40 can, for instance, be used as a charge station for electrical appliances, electric vehicles or the like due to its simple transportation with correspondingly reduced external dimensions and simple mounting in a position of use.

1. A photovoltaic module which comprises a plurality of solar cells that are each coupled to an electrically conducting or conductive and structured layer or structure for discharging the electrical energy generated in the solar cells, wherein at least one transparent carrier layer is provided on the surface of the solar cells facing away from the electrically conducting layer or structure, wherein the electrically conducting and structured layer or structure can be contacted with connections of a connection housing, wherein at least two subregions of the photovoltaic module which each have at least one solar cell are coupled to one another via a flexible connecting region and can be folded or tilted along the flexible connecting region into a position in which they are angled relative to one another and/or at least partially overlap one another, wherein the solar cells on their rear side are coupled to the electrically conducting or conductive and structured layer, which is covered by a cover layer, and that the electrically conducting or conductive and structured layer is integrated in a multilayered film arranged on the rear side of the solar cells, wherein the multilayered film forms the flexible connecting region between the at least two subregions of the photovoltaic module and/or a component thereof.

2. The photovoltaic module according to claim 1, wherein the at least two subregions each have substantially identical dimensions and/or an identical number of solar cells.

3. The photovoltaic module according to claim 1, wherein the subregions of the photovoltaic module have a regular geometric configuration such as a rectangular, in particular square, triangular, hexagonal configuration.

4. The photovoltaic module according to claim 1, wherein the conducting or conductive and structured layer or structure is embedded in the flexible connecting region.

5. The photovoltaic module according to claim 1, wherein the subregions respectively connected to one another via a flexible connecting region each comprise a plurality of solar cells and are formed with a transparent carrier layer collectively covering all of the solar cells of said subregion.

6. The photovoltaic module according to claim 1, wherein a control device is associated to at least each of the subregions of the photovoltaic module.

7. The photovoltaic module according to claim 1, wherein the dimensions of flexible connecting regions between individual, mutually overlapping subregions of the photovoltaic module are each a multiple of, in particular at least twice, the thickness of a subregion of the photovoltaic module.

8. The photovoltaic module according to claim 7, wherein the dimensions of the flexible connecting regions between subregions of the photovoltaic module are selected to differ from one another.

9. The use of a photovoltaic module according to claim 1 as a transportable photovoltaic module to be used in a folded or tilted transport condition.

10. The use of a photovoltaic module according to claim 1 as a photovoltaic module to be used with relatively angled subregions.
